(19) United States
(12) Patent Application Publication
(10) Pub. No.: US 2019/0071525 A1
(43) Pub. Date: Mar. 7, 2019

(54) SUPERCONDUCTIVE POLYACETYLENE FORMED VIA IRRADIATION OF A UREA INCLUSION COMPOUND WITH A REACTIVE DIIODOPOLYENE GUEST

(71) Applicants: Bruce Hudson, Syracuse, NY (US); Steluta Dinca, Syracuse, NY (US)

(72) Inventors: Bruce Hudson, Syracuse, NY (US); Steluta Dinca, Syracuse, NY (US)

(73) Assignee: SYRACUSE UNIVERSITY, SYRACUSE, NY (US)

(21) Appl. No.: 16/101,714

(22) Filed: Aug. 13, 2018

Related U.S. Application Data
(60) Provisional application No. 62/554,304, filed on Sep. 5, 2017.

(51) Int. Cl. C08F 38/02; C08F 2/48; C08K 5/02; C08K 5/21

(52) U.S. Cl. CPC C08F 38/02; C08F 2/48; H01L 39/121; C08K 5/21; C08K 5/02

(57) ABSTRACT

A conductive polymer formed by the photochemical condensation polymerization of polyacetylene. E,E,1,4-diiodobuta-1,4-diene ICH=CH−CH+CHI (DIBD) in a crystalline urea inclusion compound is illuminated with low power broad spectrum pulsed UV visible radiation to form an irradiated DIBD urea inclusion compound that exhibits superconductivity and can be configured into an energy storage device that is rechargeable via magnetic induction. Altnernatively, (E,E,E)-1,6-diiodohexa-1,3-5-triene may be used as the guest monomer that is polymerized in the crystalline urea inclusion compound and the resulting polyacetylene urea composite crystal may be formed into a circuit for use as a superconductor.

### CROSS-REFERENCE TO RELATED APPLICATIONS

The present application claims priority to U.S. Provisional Application No. 62/554304, filed on Sep. 5, 2017.

### BACKGROUND OF THE INVENTION

### 1.Field of the Invention

The present invention relates to a polymer that is a 1-dimensional superconductor at room temperature, more particularly, to a polyacetylene/urea inclusion compound containing this polymer with high molecular weight having exhibited photochemical elimination of iodine as seen by decrease in sample mass and loss of Raman spectral intensity indicative of very long chains that are fully extended, parallel and insulated from their neighbors. Said resulting room temperature superconducting material used to fabricate high field magnets and magnetic energy storage devices.

### 2. Description of the Related Art

Cryogenic superconducting materials are now widely used to provide high magnetic fields required for Nuclear Magnetic Resonance (NMR) spectroscopy for chemical and biomedical science and medical Magnetic Resonance Imaging (MRI). Another application of cryogenic superconductive materials is energy storage as a magnetic field. These devices are used to assist in the reestablishment of stable electric current distribution on the grid when there is a transient outage. Further, energy storage devices are notoriously inefficient and often based on materials that require rare elements, e.g., platinum. Current technologies, such as recyclable batteries, will only recycle a few thousand times before they no longer recharge. Accordingly, there is a need for room temperature superconductive materials that can be used to prepare energy storage devices, based on other mechanisms of recharging, such as magnetic induction rather than reversible electrochemistry and have longer storage times. Further the above NMR and MRI and energy storage device in use require liquid helium as the cryogenic fluid. Helium will soon be unavailable. Magnetic levitation and long distance electrical energy transmission are additional potential applications.

Polyacetylene was the first conducting polymer. It was observed that the material itself is not electrically conductive but it becomes so up addition of “dopant” species. It has further been proposed that these properties of polyacetylene are derived from an alternation in the carbon-carbon bond lengths between short and long values, this “bond-alternation” resulting in an electronic band gap. It has been argued that this is impossible because the quantum mechanical zero point energy is above the barrier of the potential energy that separates the potential energy minima and that there is thus no bond alternation. In another work, the experimental evidence for bond alternation is reviewed and found to be erroneous largely because of the disordered and cross-linked nature of the polymeric material in question.

### BRIEF SUMMARY OF THE INVENTION

The present invention comprises a method for in situ generation of a superconductive polymer, polyacetyelene, (—CH—)ₓ formed by the photochemical elimination polymerization of a conjugated organic reactive guest molecule in an inclusion crystalline solid, specifically a urea inclusion compound containing a conjugated molecule guest species with iodine atoms at each end of the molecule in iodine-iodine contacts in the urea channel. The unique environment of urea inclusion compounds imposes a geometric control on the pathway of the polymerization reaction therefore imposes a control on the structure and the length of the polyacetylene chain, resulting in a highly ordered, very long single polyacetylene chains in their fully extended all trans-conformation; the length of channel-bound polyacetylene is determined entirely by the length size of the crystal. The in-situ synthetic process used to prepare polyacetylene as a well-defined composite polymer is a novel method based on the photolytic bond scission reaction followed by formation of new carbon-carbon bond by use of radiation. More precisely, when DIBD/urea inclusion crystals are subjected irradiation of a broad mixture of visible and UV light from a low power (5 Watt) pulsed lamp, the resulting photopolymerized crystals exhibits a loss of mass due to effusion of iodine from the crystal resulting at long time in complete loss of the iodine at long irradiation time. The Raman spectrum due to the guest species evolves and at long time the intensity of scattering of the guest, the intermediate oligopolyenes and the final long chain species all disappear due to the low cross-section of very long molecules. These experimental observations are indicative of the formation of very high-molecular weight trans-polyacetylene chains that are expected to exhibit room temperature superconductivity because of the lack of bond alternation and the high frequency of the vibrations that would scattering electrons. This material can be configured into devices for the storage of electrical energy as a magnetic field and to provide high-field magnets for other applications including NMR spectroscopy, MRI imaging and magnetic levitation.

### BRIEF DESCRIPTION OF THE SEVERAL VIEWS OF THE DRAWING(S)

The present invention will be more fully understood and appreciated by reading the following Detailed Description in conjunction with the accompanying drawings, in which:

FIG. 1 is a schematic illustration of the steps involved in the preparation of a composite material and its conversion to devices according to the present invention;

FIG. 2 is a schematic of self-assembly in solution of urea inclusion compound with a fatty acid guest based on AFM images;

FIG. 3 is a schematic of two views of the structure determined by single crystal X-ray diffraction of one of the reactive guest urea inclusion compounds in this case 1,4-diiodo-1,3-butadiene (DIBD in its all trans (E,E) geometry;

FIG. 4 the formation of high-molecular weight polyacetylene and loss of iodine atoms in response to low power (5 Watt) broad spectrum pulsed radiation of a DIBD:UIC according to the present invention;

FIG. 5 is a Raman spectra of tetragonal urea, diiodobutadiene and the DIBD urea inclusion compound (UIC). Note the very low intensity at 1520 cm⁻¹;

FIG. 6 is a graph of loss of mass of an irradiated DIBD UIC crystal at 28° C. as a function of broad band irradiation time (filled circles) with subtraction of the asymptotic value of 0.61 computed from the diffraction structure; the open circles represent the increase in average polymer length in terms of the number of double bonds;

FIG. 7 is the graph of FIG. 6 but with addition of weight loss at two lower temperatures. The asymptotic value 0.61 is not subtracted;

FIG. 8 is a graph of DIBD/UIC showing mass loss in parallel to the change in Raman spectrum of the same sample;

FIG. 9 is an image of the X-ray diffraction pattern of the urea inclusion compound for the reactive guest 1,6-diiodo-1,3,5-hexatriene in its all trans E,E,E geometry;

FIG. 10 is a graph of the vibrational inelastic neutron scattering spectra of DIBD/urea-d4 single crystals. The orange and black traces represent measurements obtained at the initial and the final photopolymerization time. The green trace is a simulated INS spectrum of a polyene chain (C₁₀₀H₁₀₂) with equal bond lengths; and

FIG. 11 is a schematic of an arrangement of DIBD/UIC compound crystals prior to irradiation that leads to a closed electric path on irradiation.

### DETAILED DESCRIPTION OF THE INVENTION

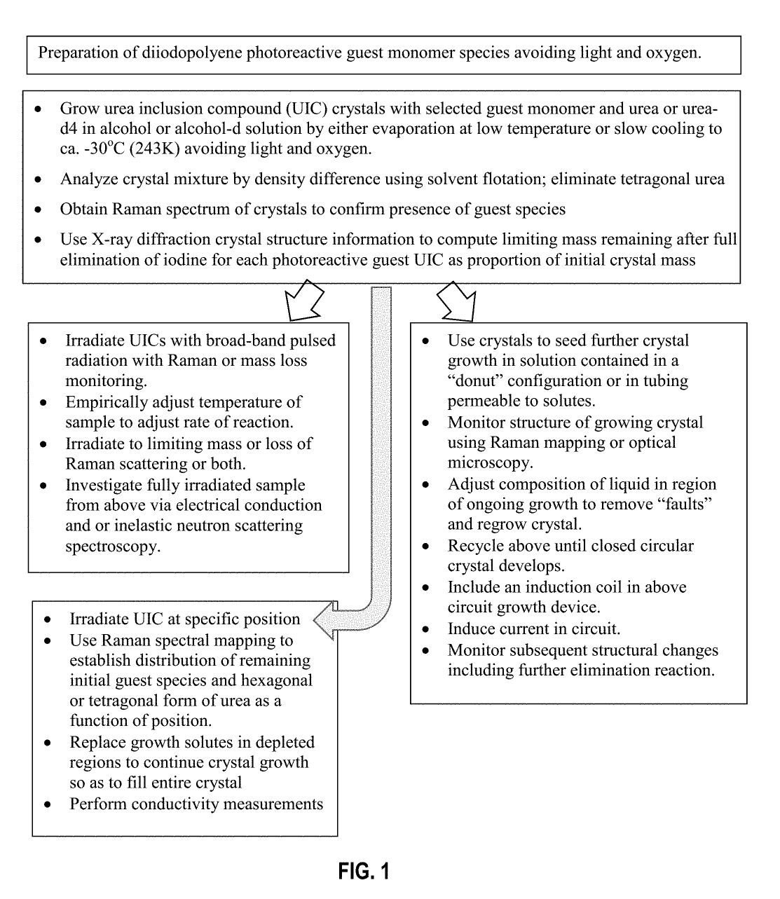

Referring to the figures, wherein like numeral refer to like parts throughout. The present invention reports the elimination polymerization process to produce high molecular weight polyacetyelene, (—CH—)ₓ chains in a way that the chains are forced to remain in their fully extended conformation and so that neighboring chains are insulated from each other so that they cannot undergo reactive cross-linking to each other, a process that is known for polyacetylene. Further, since this material will necessarily be a 1D superconductor, it will be necessary maintain a parallel orientation of the chains. To prepare such a material one must increase the degree of polymerization and control the chain conformation and orientational order. The method used to prepare parallel, extended chains of (—CH—)ₓ is based on the polymerization of a photochemically reactive guest molecule found in the self-assembling channels of an inert crystalline urea inclusion compound. FIG. 1 shows a schematic arrangement of the steps followed in order to prepare the superconducting composite polyacetylene urea inclusion compound.

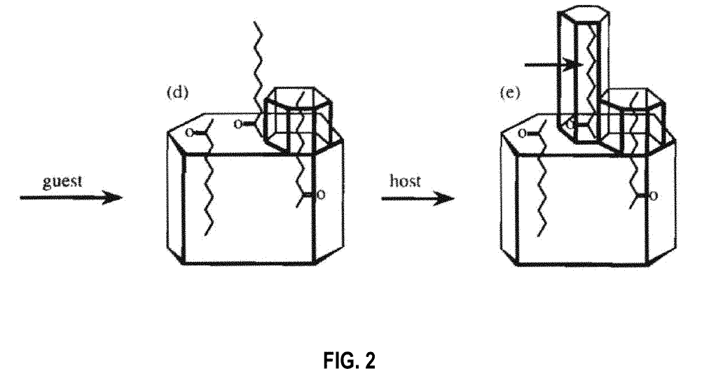

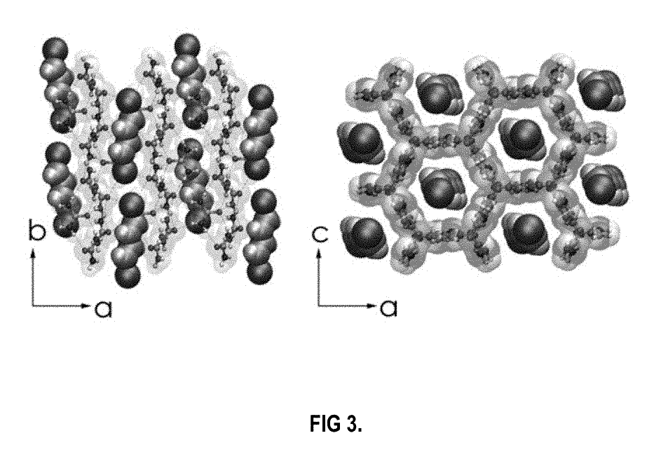

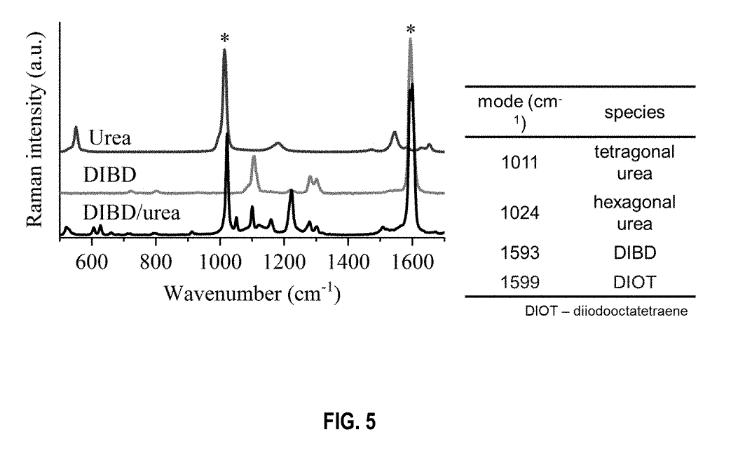

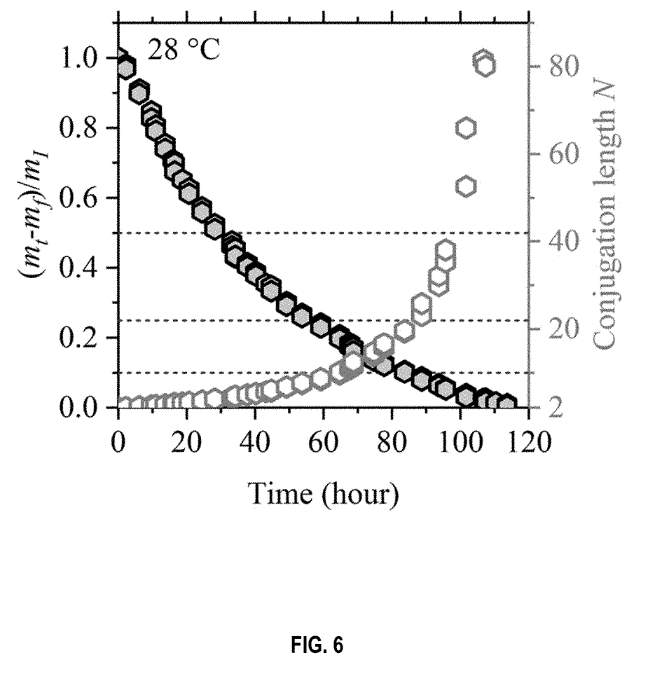

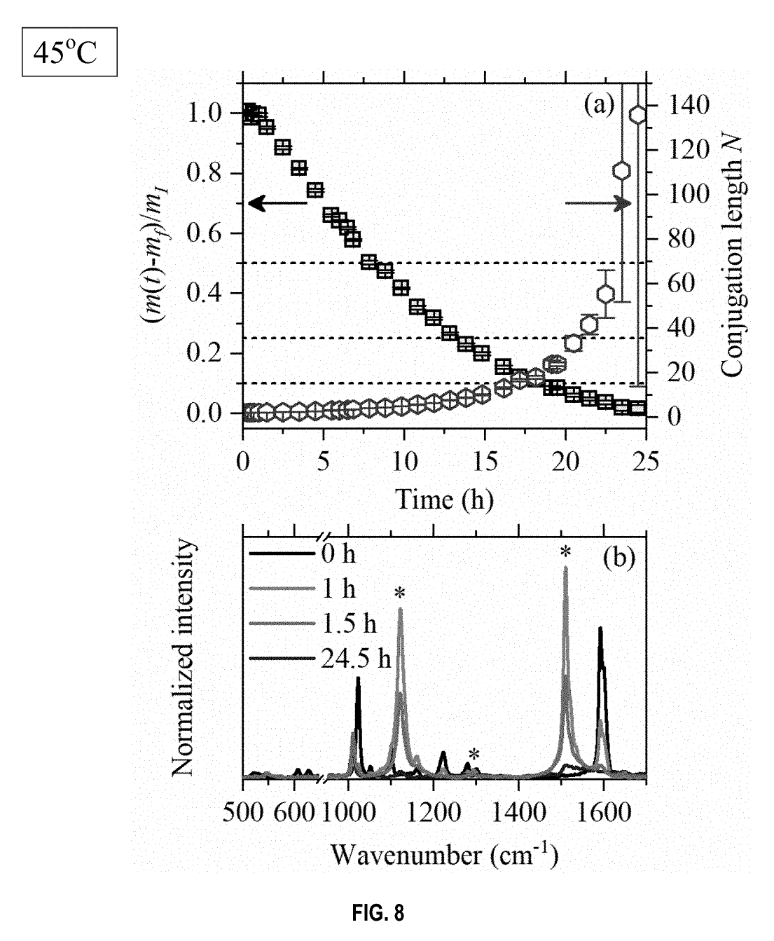

FIG. 2 and FIG. 3 shows the self-assembly process in which the hexagonal urea crystal grows around the guest species when they adhere to the growing surface . When reactive guest/inert urea crystals are subjected to light (broadband (UV/visible) or UV radiation) exposure there is breakage of the terminal carbon-iodine bonds followed by carbon-carbon bond formation between two neighboring reactive guest molecule. The progress of the degree of photopolymerization to completion as well as the characterization of the resulting channel-bound polyacetylene chains was observed with mass-loss measurements as seen in FIGS. 6, 7 and 8 and with Raman spectroscopy in FIGS. 5 and 8.

The construction of devices based on this material depends on several properties of the standard hexagonal urea inclusion compounds. One is that the host urea is inert with respect to the guest species. The second is that the guest species in the standard hexagonal compounds diffuse along the hexagonal c-axis. This is relevant to the preparation of urea inclusion compounds that have conjugated polymeric material from one end of the crystal to the other given that the polymerization process results in loss of iodine from the crystal and a consequent decrease by ca. ⅓ in the length of the material in the channel. If diffusion of the reactant species along the channel axis by amounts longer than their molecule length were not possible this would result in gaps in the channel, termination of the reaction at ca. 2/3 completion and possibly conversion of the hexagonal structure to the tetragonal form known for pure urea in the absence of guest species. In the experimental results shown below the reaction proceeds to near complete loss of iodine indicating diffusion in the channels. Presumably this results in polymer chains that are shorter than the crystal. By performing polymerization in one sub-region of the crystal (e.g., at the middle of the long c-axis dimension of the crystal) with focused radiation and then examination of the Raman spectrum at points along the c-axis of the crystal it will be possible to establish regions of tetragonal urea presumably at both ends of the crystal which can be removed mechanically or by dissolution. The resulting crystal will have conjugated polymer running end to end and be suitable for device fabrication.

It is also possible to introduce guest species by diffusion from an external solution reservoir. In applications of the present invention this could be used to form joints between one segment and another.

Device fabrication will include formation of closed loop structures. One approach to this is to prepare UIC crystals that contain reactive guest that are in the form of an annulus. This will involve seeded growth of UIC crystals in annular or constrained to be interior to permeable tubing. Details of this are below.

### EXAMPLE 1

In one aspect, the present invention involves the photochemical condensation polymerization of polyacetylene when the reactive guest species E,E,1,4-diiodobuta-1,3-diene ICH=CH−CH=CHI (DIBD) forms a crystalline urea inclusion compound (UIC) FIG. 3 that when illuminated with low power broad spectrum pulsed UV visible radiation undergoes an elimination polymerization process (eliminating iodine). The radiation results in breakage of the terminal C-I bonds. Intermediate iodopolyenes with increasing degrees of polymerization are observed by Raman spectroscopy FIG. 8 to appear in the solid crystalline material. The urea inclusion compound DIBD:UIC is, unusually, a commensurate structure with six (6) urea molecules per DIBD and no disorder. Referring to FIG. 2, the crystal growth mechanism of urea inclusion compounds is based on the formation of the hexagonal host lattice around the guest resulting in channels filled with guest molecules densely packed with iodine atoms in contact.

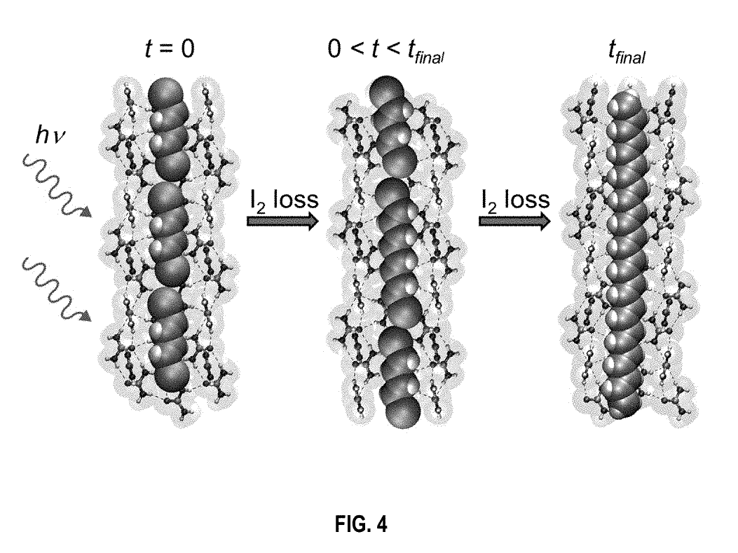

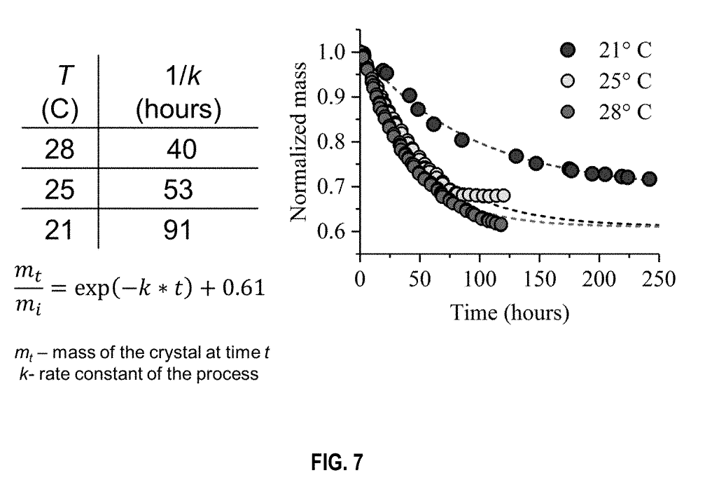

Referring to FIG. 4, the iodine effuses from the crystal resulting in a loss of mass permitting quantitative monitoring of the reaction progress FIG. 6, FIG. 7, FIG. 8. The convergence of the value of the mass of the sample to the value deduced from the known urea inclusion compound crystal structure, i.e., the mass of the original sample minus the mass of the iodine atoms, demonstrates that the photochemical elimination polymerization process is occurring throughout the entire sample. As this occurs, the Raman scattering of the diiodooligopolyenes decreases in intensity and ultimately disappears FIG. 8(b). This is consistent with the expectation for formation of very high molecular weight polyacetylene.

### EXAMPLE 2

The methodology of in situ synthesis of oriented insulated polyacetylene may be performed with a different guest species to result in standard hexagonal lattice and morphology. This is expected to result in much faster reaction kinetics due to slightly looser packing, ease of orientation of the crystal channel axis, and the capability of making polyacetylene chains that are the length of the crystal, which is currently ca. 1.5 cm. Longer crystals can be grown.

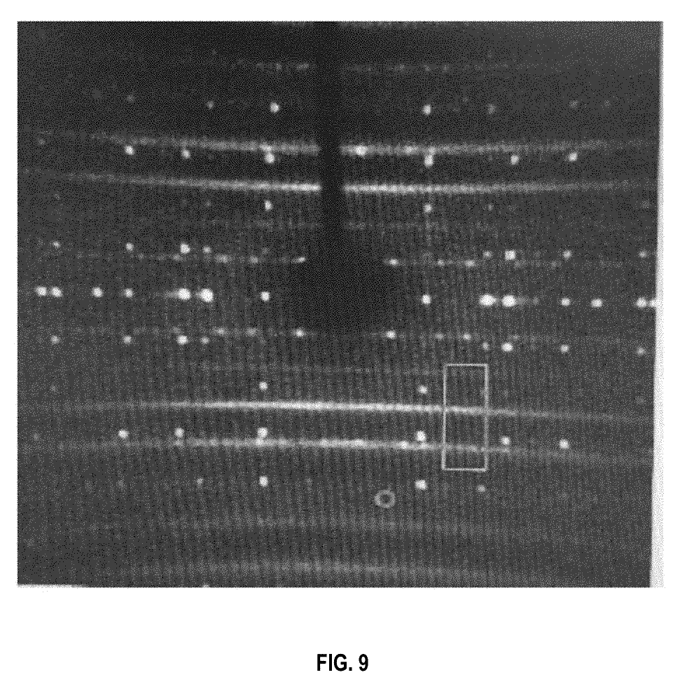

More specifically, the above example was performed on the DIBD urea inclusion crystals. The crystal morphology of this inclusion compound makes orientation of the polymer tunnel and subsequent conductivity measurements difficult. The DIBD/urea crystal is not typical of urea inclusion compounds, which are usually hexagonal needles with the guest species being disordered and much more mobile. The present example involves hexagonal needles observed with the guest species being the next higher homologue, (E,E,E)-1,6-diiodohexa-1,3,5-triene (DIHT). This guest molecule has been prepared for the first time. The all-trans (E,E,E) geometric isomer was selectively prepared. DIHT/urea inclusion compounds formed by slow cooling of a solution are macroscopic hexagonal needle prisms that have the standard helical host H-bonding network. Their X-ray diffraction pattern FIG. 9 shows that the guest DIHT monomers are significantly disordered, as known for certain a,w-dibromoalkanes and a,w-diiodoalkanes. Preliminary vibrational Raman studies with these crystals show that they readily photopolymerize to (—CH—)x at room temperature with focused 532 nm laser radiation. They are also found to polymerize with low power pulsed broad band pulsed light when the samples are held at 65 ° C.

### EXAMPLE 3

The major advantage of DIHT over DIBD is that the resulting spontaneously formed UIC crystal is of the standard hexagonal form. Not only is this useful in terms of ease of crystal orientation but also there is a lot more known about the standard hexagonal form. With both DIBD and DIHT very low temperature is needed to obtain crystals, ca −30° C. For this and other reasons, it might be possible that the next higher homologue in the series, 1,8-diiodoocta-1,3,5,7-tetraene in its all trans E,E,E,E isomer would be useful. The preparation of this material from limited irradiation of DIBD UIC should be straightforward due to the differences in solubility of the three main species present. Growth of UIC crystals using the mixture of chain lengths present at a given degree of photolysis would simplify the process. The same polymer product results.

### EXAMPLE 4

A spectroscopic method to characterize the guest polymer polyacetylene chain with application to the complete polymerization of circuit constructions.

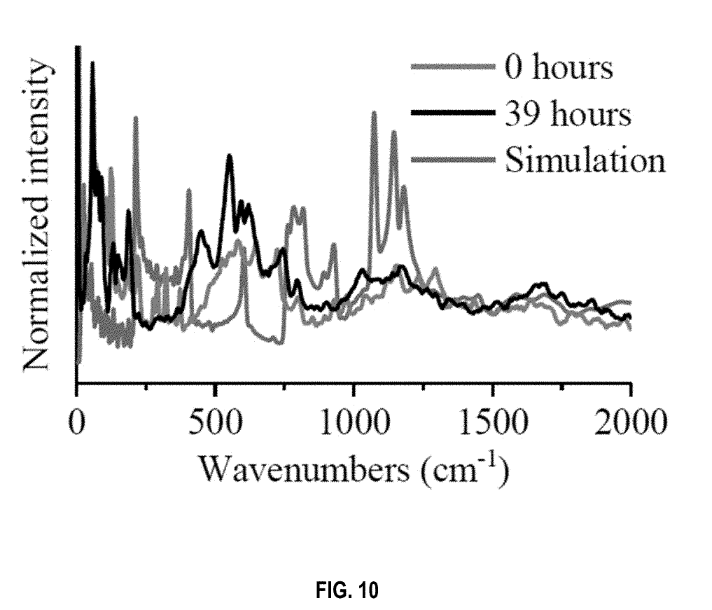

Vibrational inelastic neutron scattering spectra of the material made according to the present invention show that the polymerization continues after the Raman scattering has gone away. In FIG. 10, the INS spectra of the heavily irradiated DIBD/urea-d4 inclusion compound may be seen. Note that INS spectroscopy is much more sensitive to the motions of H atoms in a sample than to motion of any other atoms including deuterium atoms. Thus, the urea signal largely disappears by using DIBD/urea-d4 inclusion compounds in which the urea is deuterated. The INS spectra of DIBD/urea-d4 compounds shown in FIG. 27 were measured using the VISION instrument at 5 K for the limiting cases of the photopolymerization process: before and after 39 hours of irradiation. Differences between two samples are apparent: bands in the region 200-400 cm⁻¹ have completely disappeared due to the loss of starting material (DIBD) and there are indications of changes in intensity in the regions 600-800 cm⁻¹ and at 1000 and 1650 cm⁻¹ . Comparison with the simulated INS spectra of a long polyene chain (C10011102) with equal bond lengths suggests that the changes in the 600-800 cm⁻¹ , 1000 cm⁻¹, and 1600-1700 cm⁻¹ regions are indicative of monomer to polymer conversion.

### EXAMPLE 5

Details of Methods for Device Fabrication

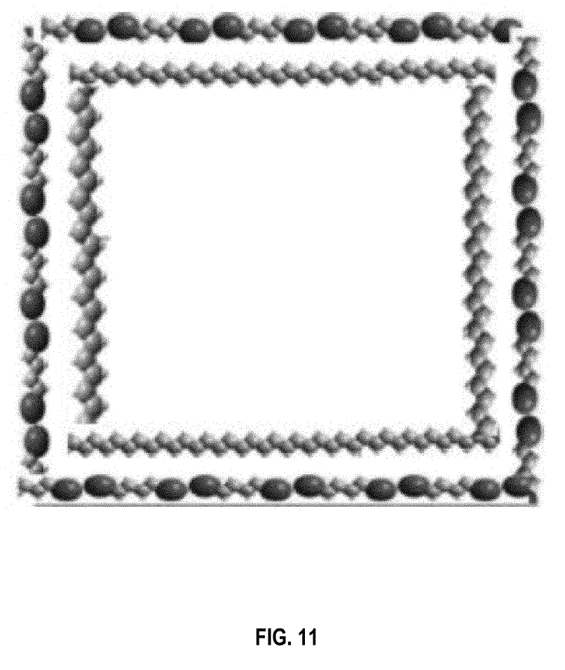

When urea molecules in solution have added organic molecules that have a generally linear shape, e.g., an n-alkane, there is spontaneous formation of an inclusion compounds that crystallize with hexagonal prism tunnel structure filled with n-alkane guest monomers. The guest molecules are packed densely with their terminal groups in van der Waals contact along the urea tunnel axis. In our case, the guest molecule is a conjugated polyene with terminal iodine atoms. When irradiated with light, iodine is lost and longer conjugated polyenes form; the iodine atoms diffuse out of the crystal. The reaction goes to completion in the sense that the loss of iodine results in a quantitative crystal mass change. Thus, diffusion of the guest species along the chains results in crystals that are filled end-to-end with polyacetylene. The guest molecules undergo one-dimensional diffusion along the tunnel axis into and from liquid reservoirs. This diffusion permits filling of the tunnels as photopolymerization at the crystal center results in empty tunnels at the ends. This capability may be used to form cyclic closed loop structures for induction of an electric current circuit as seen in FIG. 11. The present invention in this example is a magnetic energy storage device based on a crystalline composite hybrid material that contains an array of parallel one-dimensional chains. The conjugated material should be superconducting at room temperature due to the geometrical constraint of a fully extended conjugated chain formed by relatively light atoms linked by very strong covalent bonds held in a constraining crystalline compound. These crystalline constructs may be arranged so that at the microscopic level they form a closed loop structure, as seen in FIG. 11. The self-assembly of the units of this crystalline structure will include the iodine atoms whose photochemical removal results in the superconducting chain. The integrity of the system can be checked prior to photo-polymerization. An induction coil will generate a current in the closed superconducting circuit. Replication of the construct with as many units as necessary permits scale-up to a specified stored energy and power values. The recharging process involves this magnetic field from the induction coil but entails no chemical processes that have unwanted side reactions.

The method for preparation of a crystal that contains end-to-end (—CH—)x chains is to irradiate a hexagonal needle urea crystal containing a reactive diiodopolyene species with laser radiation restricted to the middle of the crystal. The crystal will be held at temperature ranging between 313 and 318 K. Mass-loss measurements will be used to monitor iodine loss during the irradiation process. Further, Raman spectra of the photopolymerized crystal will be periodically measured along the length of the crystal to survey the product polyenes. It is anticipated that: (a) the photochemical conversion of the guest to (—CH—)x and the loss of iodine will be restricted initially to the middle region of the crystal; (b) as the reaction proceeds the unreacted guest species at both ends of the crystal will diffuse into the central region as it becomes depleted in iodine. We expect that after several hours of irradiation the entire initial mass of iodine will have left the crystal and that the terminal regions of the needle will have converted from hexagonal to tetragonal urea. The resulting central hexagonal needle will contain a full bundle of (—CH—)x chains.

At this point, it may be possible to establish whether a particular composite assembled crystal is or is not a superconductor. The initial indicator will be the apparent conductance for an end to end conductivity measurement. Measurements of the temperature of the crystal as a function of current are also relevant to demonstrate superconductivity. These measurements could be performed in an insulating Dewar to provide sensitivity to even slight resistance. Another possibility is to measure the “optical conductivity” using reflectivity in the low frequency infrared region. Reflectivity should be polarized along the crystal axis. Optical conductivity of a material is proportional to the number of mobile electrons.

If these conductivity results are promising, the fabrication of a closed loop conducting structure can be performed. For example, one approach is to “short” all the termini of the channels of a polyacetylene urea composite crystal with bifunctional conjugated chemical “wires”. Circular urea inclusion crystals may also be grown from a seed in a circular well like an o-ring seal with liquid access ports. Alternatively, the crystal may be grown in a circular piece of Nafion tubing. In both cases, polymerization could be initiated in the seed region with subsequent polymerization around the circle with periodic crystal dissolution and regrowth to recharge the full ring with guest using the liquid access ports followed by further irradiation.

The present invention may also be used to grow arbitrarily long urea inclusion compounds containing 1,6-diiodohexatriene in Nafion tubing using a seed crystal in the Nafion tube bathed in a solution containing urea and DIHT that is cooled in the region where the urea inclusion crystal is growing. The Nafion tube and crystal are pulled through a warm region of dry air at a rate that is slower than the crystal growth in the cold region. In the later stage of the warm dry region the crystal is irradiated from all directions by laser light that cause photochemical polymerization of the guest. The Nafion/crystal then passes through a liquid exchange region where a non-polar solvent removes the iodine, excess solvent and dissolved urea in three consecutive wash cycles with a final rinse that is miscible with a viscous liquid that fills or coats the Nafion tubing and that can itself be photochemically polymerized. At this point, the filled tube is wound to form a helical cylinder with each winding, presumably around a spindle, being irradiated to lock in the curvature at the desired radius. The entire device can then be placed in a Kevlar box at the center of a conventional copper solenoid to charge or discharge the SMES that is filled with Epoxy.

What is claimed is:

1. An inclusion compound, comprising:
a host inclusion material; and
a linear chain of guest monomer molecules constrained within the host inclusion compound.

2. The inclusion compound of claim 1, wherein the host inclusion compound comprises a crystalline urea inclusion compound.

3. The inclusion compound of claim 2, wherein the guest comprises polyacetyelene.

4. The inclusion compound of claim 2, wherein the guest monomer is E,E,1,4-diiodobuta-1,3-diene.

5. The polymer inclusion compound of claim 2, wherein the guest monomer is (E,E,E)-1,6-diiodohexa-1,3-5-triene

6. The polymer inclusion compound of claim 2, wherein the guest monomer is (E,E,E,E)-1,8-diiodo-1,3,5,7-octatetraene

7. The method of forming a polymer inclusion compound, comprising the steps of:
self-assembling a host inclusion compound surrounding a guest monomer to form a guest/host inclusion compound;
illuminating the guest monomer with broadband radiation encompassing visible and ultraviolet spectrums until polymerization of the guest monomer occurs within the host inclusion compound; and
monitoring the time course of mass loss providing the extent of the reaction of the solid state elimination reaction.

8. A conductive circuit, comprising a polyacetylene urea composite crystal forming a circular current path.

9. The conductive circuit of claim 9, wherein the polyacetylene urea composite crystal comprises a crystalline urea inclusion compound and a conjugated chain of a guest monomer forming the polyactylene constrained within the crystalline urea inclusion compound.

10. The conductive circuit of claim 9, wherein the guest monomer is (E,E,E)-1,6-diiodohexa-1,3-5-triene.

11. The conductive circuit of claim 10, wherein the guest monomer is (E,E,E)-1,8-diiodoocta-1,3-5-7-tetraene.

12. A method of forming polyacetylene, comprising the step of forming a polyacetylene urea composite crystal through elimination polymerization in a solid state.

13. The method of claim 12, wherein the solid state is an inclusion compound.

14. The method of claim 13, wherein the inclusion compound is a urea inclusion compound.

15. The method of claim 14, wherein elimination polymerization comprise the removal of iodine.

16. The method of claim 14, wherein elimination polymerization comprise the removal of bromine.

17. The method of claim 14, wherein elimination polymerization comprise the removal of nitrogen.

18. The method of claim 14, wherein elimination polymerization comprise the removal of carbon dioxide.
